(19) United States
(12) Patent Application Publication
(10) Pub. No.: US 2023/0413671 A1
(43) Pub. Date: Dec. 21, 2023

(54) THIN-FILM THERMOELECTRIC GENERATORS CONFORMABLE TO CURVED SURFACES, AND METHODS OF USING AND FABRICATING THE SAME

(71) Applicant: Purdue Research Foundation, West Lafayette, IN (US)

(72) Inventors: Kazuaki Yazawa, West Lafayette, IN (US); Na Lu, West Lafayette, IN (US); Yining Feng, West Lafayette, IN (US)

(73) Assignee: Purdue Research Foundation, West Lafayette, IN (US)

(21) Appl. No.: 17/874,863

(22) Filed: Jul. 27, 2022

Related U.S. Application Data
(60) Provisional application No. 63/227,451, filed on Jul. 30, 2021.

(51) Int. Cl. H10N 10/17; H10N 10/01; H10N 10/82; H10N 10/852

(52) U.S. Cl. CPC H10N 10/17; H10N 10/01; H10N 10/82; H10N 10/852

(57) ABSTRACT

A thin-film thermoelectric generator including flexible base film substrate having a longitudinal direction and a transverse direction perpendicular to the longitudinal direction. Thermoelectric (TE) elements are located on the base film substrate. The TE elements arranged in columns oriented along the longitudinal direction of the base film substrate and rows oriented along the transverse direction of the base film substrate. Line grooves are located between at least portion of the rows of the TE elements and extending across the base film substrate in the transverse direction to provide flexibility to the thin-film thermoelectric generator.

### CROSS REFERENCE TO RELATED APPLICATIONS

This application claims the benefit of U.S. Provisional Application No. 63/227,451 filed Jul. 30, 2021, the entirety of which is incorporated by reference herein.

### GOVERNMENT RIGHTS

This invention was made with government support under Contract No. CMMI1560834 awarded by the National Science Foundation (NSF). The government has certain rights in the invention.

### TECHNICAL FIELD

The present invention generally relates to thermoelectric generators. The invention particularly relates to conformal thermoelectric generators configured to conform to curved surfaces and generate electrical energy directly from heat flux radiating therefrom.

### BACKGROUND

Vat photopolymerization (VPP) is one of a popular additive manufacturing (AM) technologies which utilizes the layer-based photopolymerization process to fabricate three-dimensional (3D) objects [1,2]. In the VPP process, the photocurable liquid resin is exposed to a light source and solidified rapidly in the resin vat. Due to its high printing speed, high accuracy, and wide range of applicable materials compared to other AM processes, VPP is commonly used in a variety of applications, such as micro-optics [3], biomedical engineering [4], biomimetic 3D printing [5], soft robotics [6], and 4D printing [7]. Through decades' research effort, vat photopolymerization processes have evolved into many different variations and advancements. Based on the type of curing light sources, VPP can be classified into digital light processing (DLP), stereolithography (SLA), liquid crystal display (LCD), continuous liquid interface production (CLIP) [8], volumetric 3D printing [9], and other photocuring processes [10].

Steam pipelines (e.g., superheated steam transportation having operating temperatures of 200° C. or above) are critical for district heating in populated cities in colder regions such as in northern parts of the United States and the Eurasia continent. As an example, a steam network in New York City connects about 2,000 buildings with more than 105 miles of underground steam pipes. Preventing failure of these pipelines is significant for both cost effective maintenance and security of city inhabitants.

New methods of continuously monitoring steam pipelines have been developed that use wireless network internet of things (IoT) technologies. IoT monitoring sensors may include, for example, temperature, pressure, flow rate fluctuation, acoustic emission, and localized strain. These various sensors may be operated with wireless communication electronics to timely report conditions of the pipelines for monitoring and analysis. Such time-dependent information may provide significant improvement to maintaining long-term reliability of the pipelines and to prevent or reduce the likelihood of critical failure, such as a stream explosion that occurred in New York City in 2007.

Although the IoT technologies have provided new ways of monitoring the pipelines, the operation and maintenance of these IoT sensor networks present various challenges. For example, IoT sensors require a power source for operation. However, significant portions of the pipelines are often located in difficult to access locations such as underground. Therefore, it may not be cost effective to add power lines along an existing pipeline. In addition, replacing batteries in the sensors periodically as needed may also be cost prohibitive and/or otherwise impractical.

In view of the above, it can be appreciated that there are certain problems, shortcomings or disadvantages associated with IoT sensor networks for steam pipeline monitoring, and that it would be desirable if systems and/or methods were available that were capable of at least partly overcoming or avoiding the problems, shortcomings or disadvantages noted above, such as addressing power issues associated with operating the IoT sensors within the networks.

### BRIEF DESCRIPTION OF THE INVENTION

In The present invention provides a thin-film thermoelectric generator (TEG) suitable for generating and providing power to electrical components, including but not limited those used to monitor steam pipelines. The invention also includes methods of using the TEG for power generation and methods of fabricating the TEG.

According to one aspect of the invention, a thin-film thermoelectric generator (TEG) includes, optionally, a flexible base film substrate having a longitudinal direction and a transverse direction perpendicular to the longitudinal direction, thermoelectric (TE) elements located on the base film substrate that are arranged in columns oriented along the longitudinal direction of the base film substrate and rows oriented along the transverse direction of the base film substrate, line grooves located between the rows of the TE elements and extending across the base film substrate in the transverse direction, an interlayer separating the TE elements, bottom side contacts coupling adjacent pairs of the TE elements within the columns across the line grooves on a bottom side of the inter layer between the base film substrate and the TE elements, and top side contacts coupling adjacent pairs of the TE elements within the rows between the line grooves on a top side of the inter layer opposite the bottom side thereof. The TE elements are configured to convert thermal energy into electrical energy. The base film substrate and the line grooves in combination provide for the thin-film TEG to bend and conform to a curved surface.

According to another aspect of the invention, a method is provided for using the thin-film TEG described above in a system for monitoring a pipeline having a fluid flowing therethrough at an elevated temperature relative to an ambient temperature surrounding the pipeline. The method includes locating the thin-film TEG on a section of the pipeline such that the thin-film TEG conforms to the exterior shape of the pipeline and is exposed to heat flux radiating from the pipeline, converting at least a portion of the heat flux radiating from the pipeline to electrical energy with the thin-film TEG, and providing the electrical energy generated by the thin-film TEG to one or more electrical components of the system in an amount sufficient to power or recharge the one or more electrical components.

According to another aspect of the invention, a method is provided for fabricating the thin-film TEG described above that includes printing the bottom side contacts on the base film substrate in a predetermined pattern, depositing the inter layer onto the base film substrate and the top side contacts, forming holes in the inter layer aligned with the bottom side contacts, depositing TE materials into the holes, sintering the TE materials to form the TE elements, printing the top side contacts on the top side of the inter layer aligned with the TE elements, and forming the line grooves in the inter layer.

According to another aspect of the invention, a method is provided for fabricating the thin-film TEG described above that includes providing a thin-film of the inter layer, printing the bottom side contacts a bottom side of the inter layer in a predetermined pattern, forming holes in the inter layer aligned with the bottom side contacts, depositing TE materials into the holes, sintering the TE materials to form the TE elements, printing the top side contacts on the top side of the inter layer aligned with the TE elements, and forming the line grooves in the inter layer.

Technical effects of the thin-film TEG and methods described above preferably include the ability to power electrical components by converting thermal energy to electrical energy. In certain embodiments, this may allow for powering electrical components located in isolated, hard to reach locations.

Other aspects and advantages of this invention will be appreciated from the following detailed description.

### BRIEF DESCRIPTION OF THE DRAWINGS

The embodiments may be better understood with reference to the following drawings and description. The components in the figures are not necessarily to scale. Moreover, in the figures, like-referenced numerals designate corresponding parts throughout the different views.

FIG. 1 represents a top view of a first example of a thin-film conformal thermoelectric generator (cTEG) in accordance with certain nonlimiting aspects of the present invention.

FIG. 2 illustrates a side view of a second example of the cTEG.

FIG. 3A-D represents a cTEG at various stages of manufacturing in a first nonlimiting method of fabricating a cTEG.

FIG. 4 represents a second nonlimiting method of fabricating a cTEG.

FIG. 5A-B represents a cTEG directly contacting and entirely surrounding the perimeter of a steam pipe and heat transfer related thereto.

FIG. 6 represents a diagram of a thermal resistance network (“Thermal”) in

conjunction with an electrical circuit (“Electrical”). The center hatch region represents a thermoelectric material (e.g., a thermoelectric leg of the cTEG of FIGS. 1 and 2) and the upper and lower nodes of the center hatch region represent the electrical and thermal contacts.

FIG. 7 represents a flow chart of a design optimization process.

FIG. 8 represents contribution of hot (e.g., steam) and cold (e.g., air) side heat transfer coefficients as a function of flow rate for a cTEG.

FIG. 9 represents an exemplary 8×8 array of thermoelectric legs in a checkerboard layout on a rectangular substrate with varying fill factors (0.06, 0.20, 0.80). The n-type and p-type legs are located next to each other in an alternating pattern. The right two corners of the array are reserved for wire terminals such that a total number of the TE legs is 62.

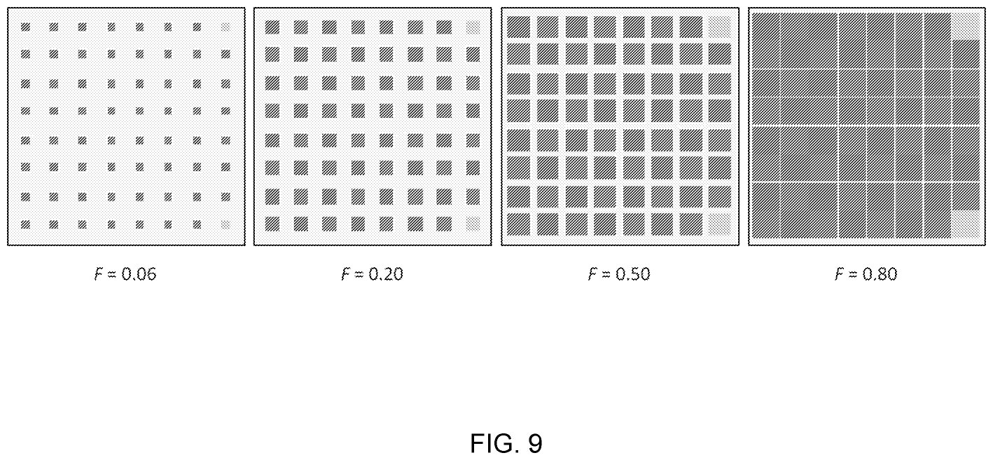

FIG. 10 represents a maximum power output and an optimum fill factor with varying TE leg length with no heat transfer enhancement on the cold side.

FIG. 11 represents power output as function of fill factor for a fixed TE leg length (5 mm) and variable TE leg lengths for a theoretical maximum power output. The dotted curves show an untreated surface, and the solid curve shows the cTEG with a pin-fin enhancement.

FIG. 12A-B represents power output as function of fill factor with varying pipe diameter from three inches (7.6 cm) to 20 inches (50.8 cm). Image (a) represents the thickness of the cTEG as unlimited and image (b) represents that the TE leg thickness as fixed to 5 mm. The power output was measured per unit pipe length (W/m), where the cTEG was applied to an entire circumference of the pipe cross section.

FIG. 13 represents power output vs flow rate for the cTEG with a fixed TE leg length of 5 mm.

FIG. 14 represents maximum power output as function of temperature difference (ΔT) between the steam and ambient air (26.85° C.) while the TE leg length was constrained. The dots are calculation results with an exponential curve fitted. The trend was nearly proportional to the square of ΔT.

FIG. 15A-B represents material cost per power output ($/VV) as a function of fill factor in various pipe diameters. Image (a) represents cTEG with unlimited TE leg length and image (b) represents the cTEG with a fixed leg length of d=5 mm. Material prices were $500/kg with density of 8200 kg/m3, $5/kg with density of 965 kg/m3, and $175/kg with density of 1420 kg/m3.

FIG. 16 represents power output per unit area vs temperature difference across the cTEG. Dots were experimental data and the broken curve was a model based on the effective properties extracted from the experiments. The dots follow a trend of ΔT².

FIG. 17 illustrates an example of a system in which electronics are powered by a cTEG.

### DETAILED DESCRIPTION

Disclosed herein is a conformal thermoelectric generator (cTEG) and a method of using the cTEG to generate electrical energy directly from heat flux radiating from curved surfaces and powering devices therewith. A nonlimiting example that will be referenced throughout the description will be the use of the cTEG to harvest heat flux from a stream pipeline to provide electrical energy to sensors within an IoT sensor network configured to monitor the stream pipeline. However, this application is merely exemplary as the cTEG may be used in various other applications for heat and electricity co-optimization in fields such as but not limited to geothermal activities, deep sea monitoring, space exploration, power plant power generation, and automotive fuel efficiency.

Since steam pipelines transport heat energy, there is a potential for harvesting a fraction of energy dissipated from these pipelines to power the IoT electronics/sensors of the IoT sensor network, especially in difficult to reach locations of the pipeline. For example, thermoelectric generators (TEGs) are solid state devices that are capable of converting heat flux (i.e., temperature differences) directly into electrical energy through a phenomenon called the Seebeck effect. Such TEGs may be used to power the IoT electronics/sensors by harvesting the heat dissipated from the steam pipelines.

However, several limitations exist that may prevent the use of conventional TEGs within the IoT sensor network. Existing TEGs generally include rigid, planar substrates which are not capable of directly conforming to the curved exterior surfaces of the pipelines. While a thermal interface component may be provided between the pipelines and the TEGs to address this issue, this additional component will likely result in a substantial heat loss across the thermal energy flow path limiting the power generation capabilities. In addition, existing TEGs may include heat input surfaces that do not match the thermal resistances of the steam pipelines which can lead to poor performance.

Some research has been conducted on flexible TEGs. However, the reported flexible TEGs generally comprise materials with relatively poor energy conversion performance that is not sufficient to replace existing TEGs. For example, certain polymer based TEGs have been reported that had a figure-of-merit less than half that of conventional semiconductor-based TEGs. In addition, while these polymer-based TEGs may have lower thermal conductivity (a positive property for thermoelectric applications), enhancement of their electrical conductivity has been an significant issue and therefore these polymer-based TEGs have shown significant parasitic heat loss.

In contrast, the cTEG disclosed herein is configured to conform to curved surfaces for direct contact with the exterior surfaces of the pipelines and to generate sufficient electrical energy from the pipelines to power typical IoT electronics/sensors.

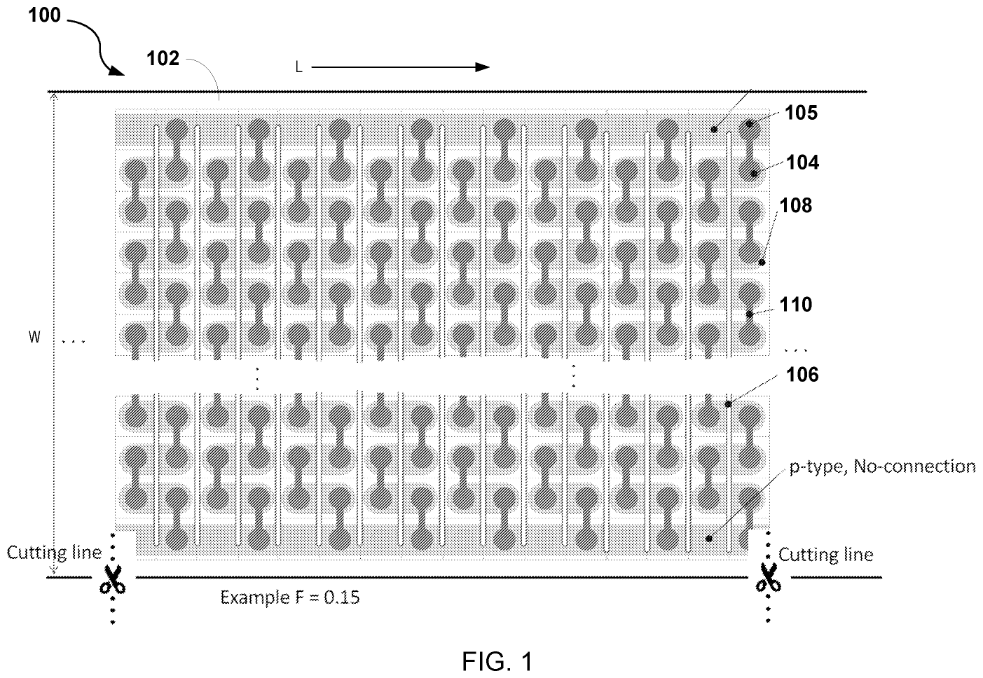

FIG. 1 represents a top view of a first example of a cTEG 100. The cTEG 100 includes a multi-layered thin-film having a flexible base film substrate 102 with spaced apart thermoelectric (TE) elements thereon (e.g., p-type 104 and n-type 105). For convenience, the TE elements of the cTEG 100 will be described as being arranged in columns oriented in a longitudinal direction (L) of the thin-film and rows oriented across the thin-film and perpendicular to the columns. The rows may span the width (w) of the thin-film, which may be the print width according to manufacturing techniques.

As represented, the cTEG 100 includes channels, referred to herein as line grooves 106, located between the rows of TE elements and extending across the thin-film. As described herein, a bottom side of the thin-film corresponds to a side with the base film substrate 102 and a top side of the thin-film corresponds to the opposite side of the thin-film (i.e., having openings to the line grooves).

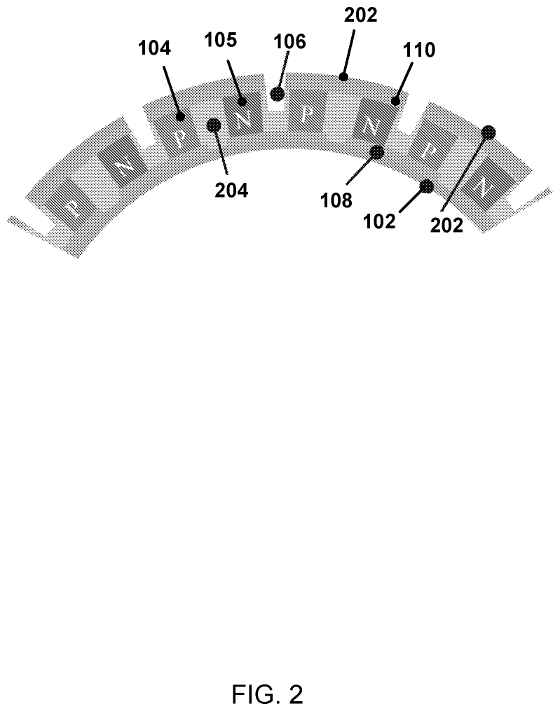

The TE elements are separated by an inter layer (e.g., PDMS) (the inter layer is not visible in FIG. 1 for ease of illustration, but the inter layer 204 visible in FIG. 2). Adjacent pairs of the TE elements are coupled within the columns across the line grooves on the bottom side of the thin-film with bottom side contacts 108. Pairs of TE elements may be coupled within the rows on the top side with top side contacts 110. The width of the contacts shown in FIG. 1 may vary, but was reduced from ease of illustration.

The thin-film may be manufactured with various production methods and/or combinations of methods. For example, the TE elements may be formulated by roll-to-roll methods such as inkjet printing, screen printing, transfer printing, etc. Alternatively, the TE elements may be secured between the bottom side and top side contacts pre-printed on the base film substrate with methods such as laser sintering, laser additive (3D printing), etc.

FIG. 2 illustrates a side view of a second example of the cTEG 100. The CETG may include a top film layer 202. The top film layer may be interrupted by line grooves 106. In the example illustrate din FIG. 2, the line grooves 106 are disposed between every other row of thermoelectric elements. Other embodiments are possible where line grooves are disposed between differing numbers of rows to achieve the desired amount of curvature/structural integrity.

The top contacts 110 may be at least partially disposed between TE elements and the top film layer. In the example illustrated in FIG. 2, the top contacts 110 and bottom contacts 108 are oriented in the same direction. An inner layer 204 may be disposed between the top contact 110 and bottom contact 108 and/or between the top film layer 110 and base film layer 108.

Depending on the embodiment, the base film 102 and the top film 202 may or may not be included. Suitable materials for the base film 102 and/or top film 102 may include, for example, PDMS and/or Kapton or any other flexible and insulative material. The base film and top film top and bottom films provide insulating layers to conserve the heat within the thermoelectric device. As such the device will convert thermal energy into electricity.

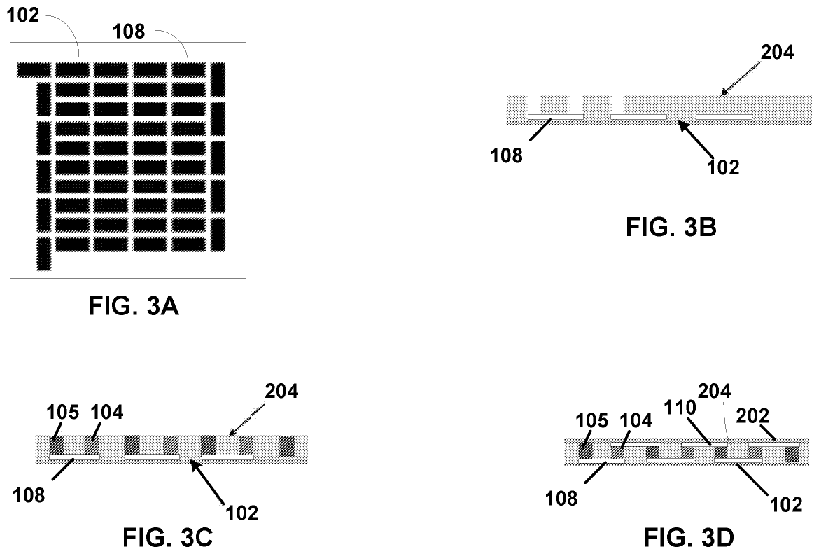

FIG. 3A-D illustrates a cTEG at various stages of a nonlimiting first method of fabricating the thin-film. Referring to FIG. 3A, the bottom side contacts may be printed on the base film substrate in a predetermined pattern. Referring to FIG. 3B, the inter layer 204 may be deposited onto the base film substrate and the bottom side contacts 108. Holes may be formed in the inter layer in locations corresponding to desired locations of the TE elements. Referring to FIG. 3C, the holes may be filled with TE materials, for example, as an ink and sintered to form the TE elements. Referring to FIG. 3D, the top side contacts 110 may then be printed on the top side of the thin-film. Optionally, an additional layer may be added to the top side of the thin-film. Such additional layer may be substantially the same material as the base film substrate.

Once the components of the thin-film have been fabricated as described, the line grooves may be formed therein. The line grooves may be added to either side (top or bottom) of the cTEG. For example, the line grooves may be added to the base film 102 or top film 202. Alternatively or in addition, the line grooves may be added to the intermediate layer. A 3D printed line grooves mold may be used during the process. Alternatively or in addition, the line grooves may be formed by cutting or some other subtractive process.

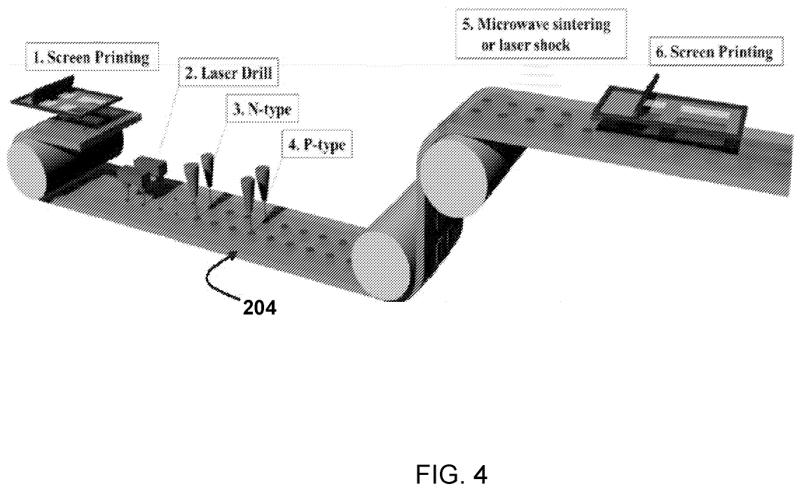

FIG. 4 represents certain steps of a nonlimiting second method of fabricating the thin-film. In this example, the base film substrate may be omitted or added after fabrication of the other components of the thin-film. As represented, the bottom side contacts may be printed on a bottom side of a film formed of the inter layer material. (1). The holes may be formed with, for example, a laser drill (2) and filled with the TE materials, and sintered to form the TE elements (i.e. n type or p type) (3-5). The top side contacts and, optionally, top film may then be printed over the TE elements (6). Subsequently, the line grooves may be formed in the inter layer. In some examples, the line grooves will be pre created during the process for making inter layer materials (PDMS). Then inter layer materials with line grooves will be manufactured in roll-to-roll process (FIG. 4).

The cTEG and its components may be formed of various materials. As nonlimiting examples, the TE elements (e.g., TE legs) may be formed of TE materials conventionally used in rigid, semiconductor-based TEGs, such as but not limited to bismuth telluride (Bi2Te3).

Preferably, the TE materials do not include polymer-based materials, such as conducting polymers, organic/inorganic hybrids, or continuous inorganic films. Although polymers may provided an advantage of relatively low thermal conductivity, for example, in a range of about 0.5 W/(m*K) or lower, the thickness required for such materials to reach a suitable power output is within a centimeter range which is undesirable for the present applications. This relatively large thickness is due to a low heat flux available in the system.

The cTEG provides for electrical energy generation using high performance TE materials while simultaneously providing a mechanically flexible thin-film structure. This structure may be manufactured in roll-to-roll processes that produce repetition of a minimum unit and promote ease of adjustability to various physical parameters of the cTEG (e.g., TE element size, fill factor, etc.). In certain embodiments, the cTEG may include cutting lines periodically located along a length of the thin-film cTEG that extend across the width of the cTEG (e.g., transverse direction). The cutting lines may be configured to be cut to adjust the length of the cTEG without affecting the overall operation of the cTEG and/or its components.

The simplest structure of the thermoelectric power generator (TEG) is a single piece of the thermoelectric leg (either p-type or n-type) contacting on the pipe surface as the hot side. Another side of the leg is exposed to ambient air to reject the heat via natural air convection and radiation. We considered that the leg is formed by sintering the small particles of the material. In harvesting heat energy to convert electricity for IoT utilization, heat sources most likely be a fluid, such as hot gas, hot water, fossil oil, steam, etc. Therefore, the pipe exterior wall surface is a key geometry to consider to recover the heat with thermoelectrics. As one of the examples, we investigated the design of conformal TEG (cTEG) module directly attached to cylindrical steam pipeline. The importance of this mechanically “conformal” feature is to minimize the thermal contact conductance through the interface. The larger the conductance, the more we have the heat that is the source of power per unit area. Especially for a case of small temperature gradient across thermal path, this is critical. The cTEG has a moderate mechanical flexibility, called bendable, so that the contact face aligns to the heat source surface such as cylinder pipes. This conformability also could work well for retrofitting to many existing pipelines.

Nonlimiting embodiments of the invention will now be described in reference to experimental investigations leading up to the invention. The cTEG was investigated to determine potential for locally harvesting heat energy from a steam pipeline and whether such generator would be capable of providing sufficient power to support local IoT sensors.

Typically, a branch pipe is used to connect a steam pipeline supply to buildings. The branch pipe may have a diameter in the range of about 6 to 12 inches (0.15 to 0.3 m). Therefore, a six inch branch pipe was considered for the following investigations. Further, it was assumed that the branch pipe would be locate3d in a relatively tight space that would prohibit access for running power lines or replacing batteries. Therefore, it was assumed that the branch pipe was located in a confined space having a cross section of 1 m height×1 m width. The air temperature in the confined space was assumed to always be at about 27° C., which was considered conservative relative to real world examples in relatively cooler climates.

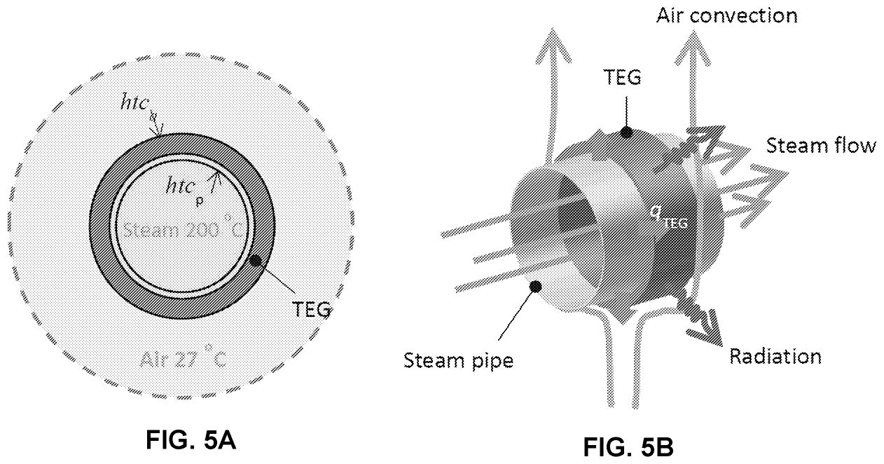

FIG. 5A-B represents the cTEG directly contacting and entirely surrounding the perimeter of the branch pipe. FIG. 5A shows a cross section of the pipe and TEG. FIG. 5B illustrates a perspective view of the pipe and TEG. Steam flow direction, air convection direction, radiate heat direction, and heat energy flow across the cTEG are represented with arrows. Typically, steam pipelines are covered with an insulation material to reduce heat loss. Therefore, it was assumed that exteriors surfaces of the branch pipe would be thermally insulated in locations other than those in contact with the cTEG.

The cTEG used for the investigations included 40 pairs of n-type and p-type TE legs uniformly arranged in an array on a 40 mm×40 mm area. The TE elements included BizTe3 with mean zT value of 0.85 at the mean operation temperature. The n-type and p-type TE legs were 1 mm×1 mm with variable heights. A polyimide material was used for the base film substrate, in this instance Kapton, and had a thickness of about 273 μm. The base film substrate had a thermal conductivity of about 1.76 W/(m*K) at 300K. PDMS was used between the legs as the inter layer for the gap fill. The thermal conductivity of PDMS was about 0.15 W/(m*K) for the entire operational temperature range. Since PDMS is an insulating material, a passivation layer between the contacts was not necessary. By providing a gap fill material, radiation thermal cross talk between the hot and cold interim walls was prevented. The bottom side and top side contacts included a 30 microns thick metallization pattern having an electrical conductivity of about 6×107 S/m.

Modeling was performed using the above described parameters. The model considered a single TE leg and assumed a uniform array of p-type and n-type junctions with the same property values except for the polarity of the Seebeck coefficient. All material properties took the average value from temperature dependency. By formulating from energy balance equations, the maximum power output was found from true external boundary conditions (e.g., steam and air). The steam was considered to be a relatively large heat mass (e.g., supplying about 37.8 kW of heat per pipe based on the latent heat alone) with about 0.19 kg/s of flow rate. Since the power needed for a typical IoT sensor was considered to be in the range of about a few 100s of mW each, it was determined that energy conversion efficiency was immaterial, whereas maximizing power output per device was considered to be a more important consideration as it is directly related to the cost of the proposed energy generation system.

Heat transfer components were investigated and modeled with using selected empirical correlations. The heat source was a super-heated steam flow with a fixed temperature of 200° C., which was the hot side temperature reservoir. This meant that the temperature of the steam had negligible change during flow through portions of the pipe used for heat energy harvesting by the cTEG. This was considered a reasonable assumption as long as the sensible heat supplied by the steam flow was significantly large compared to the heat extracted by the local power generator(s) (e.g., no phase change occurs). The cold side temperature reservoir was defined by the ambient temperature 27° C. of air via passive convection or surrounding wall(s) via radiation heat transport. In order to allow the natural convection with gravity effect, a sufficient surrounding space was assumed for the pipe.

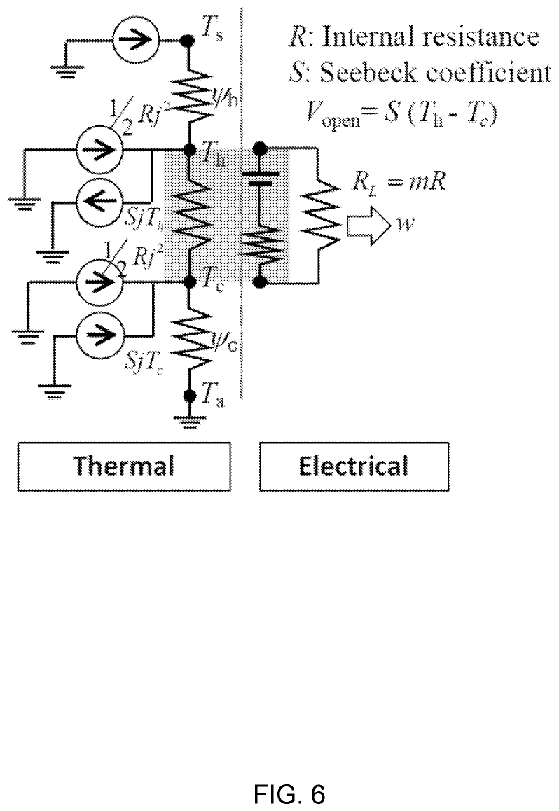

FIG. 6 represents a diagram of a thermal resistance network (“Thermal”) in conjunction with an electrical circuit (“Electrical”). However, for simplification, the electrical side of the diagram contains a single TE leg. In real world cTEGs, the TE legs may be connected electrically in series and thermally in parallel. The electrical current flow and the heat flow deeply interplay each other, hence these effects cannot be separately analyzed. In FIG. 6, ψₕ and ψ_{c} represent thermal resistances for heat transfer on the hot side and cold side, respectively.

The known temperatures of the hot side, Tₕ, and the cold side, T_{c}, allowed for determination of the power output per unit area w [W/m2] using equation (1).

$$w = \frac{m σ {S}^{2}}{{( 1 + m )}^{2} d} {( {T}_{h} - {T}_{c} )}^{2} \qquad ( 1 )$$

where, m was electrical load resistance ratio m=R_{L}/R, σ was electrical conductivity (S/m), S was the Seebeck coefficient (V/K), and d (m) was the length of the thermoelectric legs. If d is very large, power output diminishes where the temperature difference (Tₕ−T_{c} cannot exceed the entire temperature difference of the system boundary (Tₛ−Tₐ). On the other hand, if d is very small, the temperature difference (Tₕ−T_{c} becomes very small. Hence there should be an optimum d to maximize the power output as represented in equation (2).

dₒₚₜᵢₙᵢᵤₘ=km(ψₕ+ψ_{c}) (2)

where, k (W/(m*K)) was thermal conductivity and ψₕ, ψ_{c} (m²*K/W) were thermal resistances of the hot and cold side of the legs. These two temperatures depended on the thermal resistance as well as the electrical heat generation internal of electrical circuit as mentioned above. Hence both electrical and thermal optimization are preferably performed simultaneously. Since the R_{L} was considered to always matched to the optimum, then,

m=\sqrt{1+ZT̅} (3)

where, T′ was the operation temperature T′=(Tₕ+T_{c})/2 and Z was the figure of merit of the TE material Z=σS²/k.

The analytical maximum power output per unit area was determined by knowing both the hot and cold side temperature of the TE leg as represented in equation (4).

$${w}_{maximum} = \frac{mZ}{{( 1 + m )}^{2}} \frac{k}{{d}_{optimum}} {( {T}_{h} - {T}_{c} )}^{2} \qquad ( 4 )$$

From the given boundary temperature by knowing the optimum parameter dₒₚₜᵢₘᵤₘ, the maximum power output was found as equation (5).

$${w}_{maximum} = \frac{mZ}{{{α}^{2} ( 1 + m )}^{2}} \frac{k}{{d}_{optimum}} {( {T}_{s} - {T}_{a} )}^{2} \qquad ( 5 )$$

where, a was the factor determined by the external thermal resistances and internal thermal resistance of the TE legs. Typically, this value was near two as both the hot and cold thermal resistances were similar.

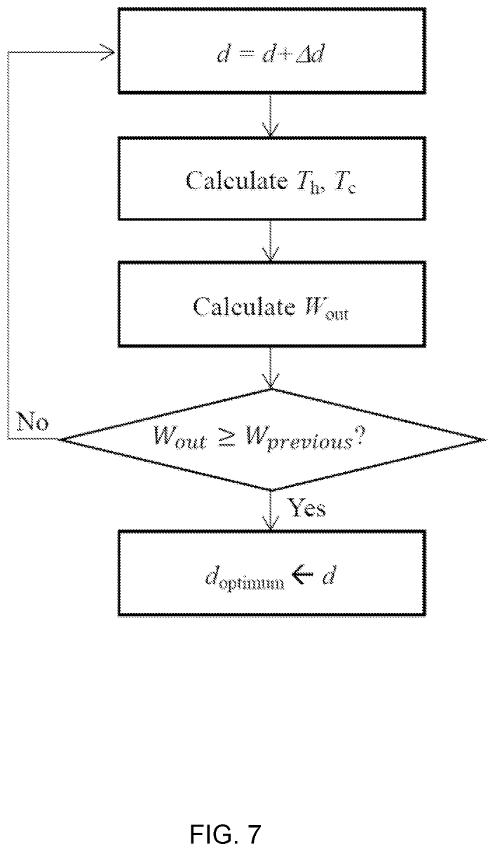

In the process of finding optimum design: dₒₚₜᵢₘᵤₘ, Tₕ, and T_{c} were still involved in the equation. An iterative calculation was conducted with the given fill factor and number of TE legs per unit area to obtain a solution. It was known that only one global optimum point existed across the entire variation of TE leg length d. Also, the power output tended to be insensitive to the parameter change near at the peak. Hence, an algorithm was applied as represented in FIG. 7.

Internal heat transfer from the steam (200° C.) to the interim wall surface of the six inch diameter steam pipe was determined by utilizing the Sieder and Tate correlation for fully developed turbulent flow. This correlation included the temperature gradient of bulk flow and a nearby wall to reflect the temperature dependency of the fluid property.

$${Nu}_{D} = 0.027 {Re}_{D}^{4 / 5} {Pr}^{1 / 3} {( \frac{μ}{{μ}_{w}} )}^{0.14} \{ valid for {Re}_{D} > 10 , 000 \} \qquad ( 6 )$$

where subscript D stood for the pipe diameter, p was bulk viscosity and pw was viscosity near the nearby wall. The flow rate of the steam was taken into account as temperature-dependent and pressure-dependent specific heat and viscosity. The pipe was considered to have a heating capacity of 37.8 kW with the steam flowing therethrough with a mass flow rate of 0.19 kg/s and with a Reynolds number of Re_{D}>1.03×10⁵ with a bulk velocity of 22 m/s. Along the pipeline, convection between the bulk steam flow and the interim wall of the pipe was a function of total heat loss through the pipe exterior. Since the pipe was covered by a thermal insulator and only a fraction of the exterior surface was used for the thermal energy harvesting, the steam flow was considered as temperature reservoir. The heat flow Q by steam was determined by the sensible heat brought to the ideal condenser at saturate temperature Tₛₐₜ as

Q=ρuACₚ(Tₛₜₑₐₘ−Tₛₐₜ) (7)

where u=μRe_{D}/(pD). Here, the bulk velocity u was determined. Then, the Reynolds number was inserted into equation (6) to determine the heat transfer coefficient as

htCₚ=k_{f}Nu_{D}/D (8)

Under the condition stated above, the Nusselt number Nu_{D} was 261 and the heat transfer coefficient was 55 W/(m²*K).

The heat transfer from the exterior of the pipe to the ambient was calculated based on passive air convection and the radiation heat transport to the surrounding walls. The model considered only the section of the pipeline where the cTEG was applied. The correlation by Churchill and Chu was used for the air convection from an infinitely long horizontal cylinder to ambient, where the cylinder was suspended in the air with no thermal contact. The surrounding space was assumed to be sufficiently large so that airflow induced by buoyancy was not disturbed. The Nusselt number was determined as

$${Nu}_{D} = {\{ 0.6 + \frac{0.387 {{Ra}_{D}}^{1 / 6}}{{[ 1 + {( 0.559 / Pr )}^{9 / 16} ]}^{8 / 27}} \}}^{2} \qquad ( 9 )$$

where the diameter-basis Rayleigh number Rap was found as

$${Ra}_{D} = \frac{ℊ β ( {T}_{c} - {T}_{a} ) {D}^{3}}{v α} \qquad ( 10 )$$

where g is gravity, β was the coefficient of thermal expansion, v was viscosity and a was thermal diffusivity. The non-linear radiation heat transfer takes effect in a same order of natural convection when the convection is weak even at the temperature excess of the surface is as high as 10s degrees. In this model, a gray body thermal emission was considered from the pipe surface with an emissivity value of 0.85 (oxidized and untreated). The surroundings were considered infinitely far from the pipe compared to the pipe diameter, so that far infrared wavelength reflection coming back from the surrounding wall was minimal and neglected. In this case, one-way heat removal by radiation was considered.

$${htc}_{a \_ eff} = \frac{{k}_{f}}{D} {Nu}_{D} + σε ( {T}_{c}^{4} - {T}_{a}^{4} ) / ( {T}_{c} - {T}_{a} ) \qquad ( 11 )$$

where k_{f} was thermal conductivity of air, σ was the Stefan-Boltzmann constant, and was emissivity of the pipe surface.

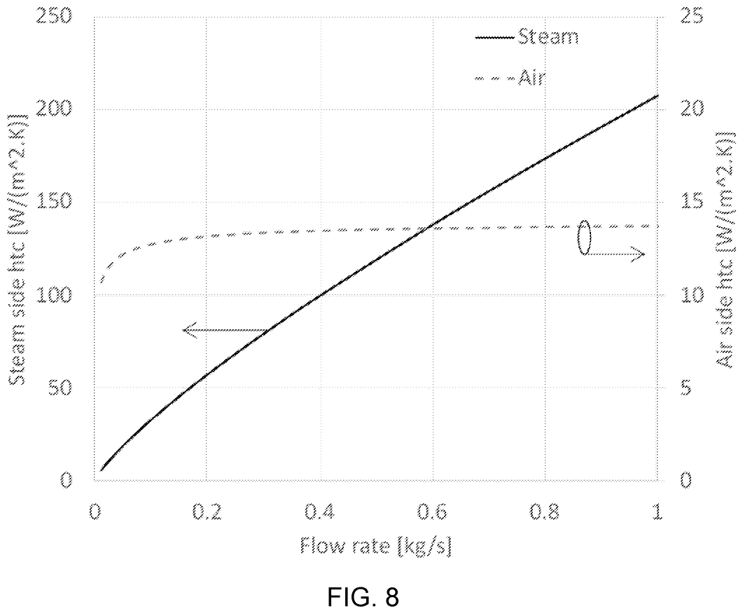

FIG. 8 represents the contribution of the hot and cold side heat transfer in a system determined by integrating the above with thermoelectric generator model.

In order to investigate maximization of the power output per given dimension, calculations were based on the temperature independent material properties: thermal conductivity of 1.07 W/(m*K), electrical conductivity of 58,750 (1/Ω*m), and Seebeck coefficient of 191 pV/K. The material zT value was 0.85. As the property profile changed significantly with changing doping level and/or the processes, temperature dependent properties were not considered.

The temperatures at the hot and cold side of the cTEG were not equal to the boundary temperatures (steam temperature of 200° C. and ambient temperature of 27° C.), which were temperature reservoir (or thermal bath). Depending on the internal and external thermal resistances, the heat flow cross the TE legs was determined. Hence the actual temperatures at the terminals of the TE legs were determined by the thermal diffusion as well as the additional heat flow induced by allowing electrical current flow across the TE legs. The electrical and thermal energy transports were co-optimized as both were interdependent.

Certain important factors of the cTEG were the fill factor F (fractional area coverage of TE leg), the TE leg length d, and the number of TE legs per unit area N. Design optimization was conducted focusing on the impact of fill factor and leg length while coordinating the manufacturing process. It was known that the power output per unit area was independent to N as long as d and F were kept constant. Hence, the impact of TE leg length and fill factor were investigated. Following figure visualize regarding how the TE elements occupy the footprint by varying fill factor, the calculations were conducted in a range from 0.02 to 0.99 (e.g., 2% to 99%).

In this investigation, some level of mechanical flexibility was desired to the cTEG to conform to the curvature of the cylinder pipe surface. The flexible cTEG was limited to a thickness of 10 mm or less for the pipe diameter of six inch (about 150 mm). A maximum module thickness of 5 mm was set as the threshold of evaluation, meaning that the maximum allowable TE leg length was 5 mm.

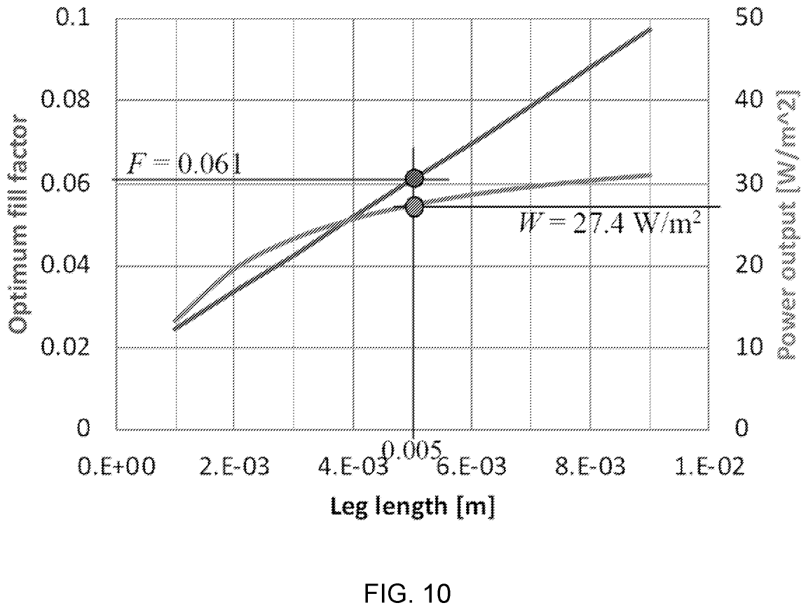

FIG. 10 represents a maximum power output and an optimum fill factor with varying TE leg length. No heat transfer enhancement on the cold side was considered. At the maximum power output condition, the relationship between the TE leg length and fill factor was proportional.

Based on the given conditions, the cold-side external thermal resistance dominated the net thermal resistance across the system (htcₐ<htcₚ). If a larger thermal harvesting was desired, the heat flow through the generator was enhanced by reducing the cold side thermal resistance as long as the generator was optimally designed. In practice, enhancement of natural convection is considered a primary challenge for the improvement. Therefore, a pin-fin heat transfer enhancement on the cold-side passive air convection was investigated in this investigation. The Aihara's correlation was used for circular pin-fins in the calculation. The heat transfer was found using a Rayleigh number Ra* based on the horizontal pin spacing Sₕ which was found as

$${Ra}^{*} = \frac{Pr ℊ β ( {T}_{w} - {T}_{a} ) {s}_{h}^{4}}{{Hv}^{2}} \qquad ( 12 )$$

where g was gravity, β was the coefficient of thermal expansion, v was viscosity, and H was the effective vertical length of the pin-fin array. Then, the Nusselt number with pin-fin array was described as

$$( \frac{π {d}_{p}}{2 {s}_{v}} ) {Nu}_{p} = {\frac{{Ra}^{* 3 / 4}}{20} [ 1 - {e}^{- \frac{120}{{Ra}^{*}}} ]}^{1 / 2} + \frac{{Ra}^{* 1 / 4}}{200} \qquad ( 13 )$$

where dₚ was diameter of the circular pin-fin, and Sₕ was vertical pin spacing. The heat transfer coefficient was then found as

$${htc}_{pin} = {Nu}_{p} \frac{{k}_{f}}{{s}_{h}} \qquad ( 15 )$$

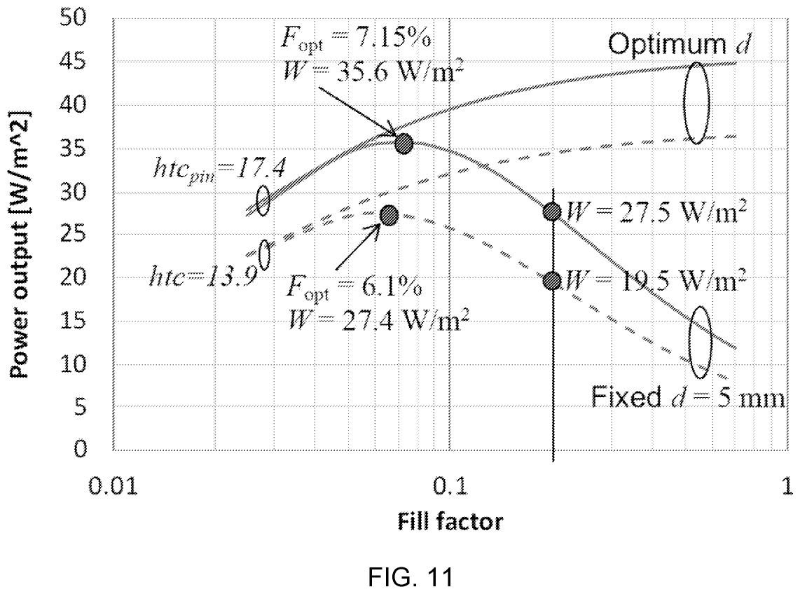

The pin-fin enhancement provided an improvement from 13.9 W/(m²*K) to 17.4 W/(m²*K) in the heat transfer coefficient. The impact of this heat transfer for the cTEG is represented in the FIG. 11.

A theoretical maximum power output with an ideal cTEG was determined to have a potential of up to 48 W/m² range, where the optimum TE leg length was significantly large for the larger fill factor as seen in FIG. 10. However, the cTEG most likely will have a power output below the maximum power output with a shorter TE leg length than the optimum. That is due to a limitation of the length by mechanical flexibility of the cTEG (d≤5 mm).

FIG. 11 represents power output as function of fill factor with fixed and optimized TE leg lengths. From a manufacturing standpoint, reducing the fill factor presents a significant challenge to secure the electrical and thermal contacts. For this investigation, a fill factor of 0.2 was used which was considered to be a practical parameter for actual practice.

The performance of the cTEG in practice was estimated to generate 19.5 W/m² with a thickness of 5 mm and a fill factor of 0.2, according to the material properties and heat transfer conditions. This translated into a power harvesting with a six inch diameter steam pipe to be more than 40 W/m of power output per pipe length. As such, a cTEG that entirely covers the perimeter of the steam pipe would only be required to be a few centimeters long to provide sufficient power supply to a typical IoT sensor. Alternatively, a cTEG that covers only a quarter of the circumference of the steam pipe could be less than 10 cm long.

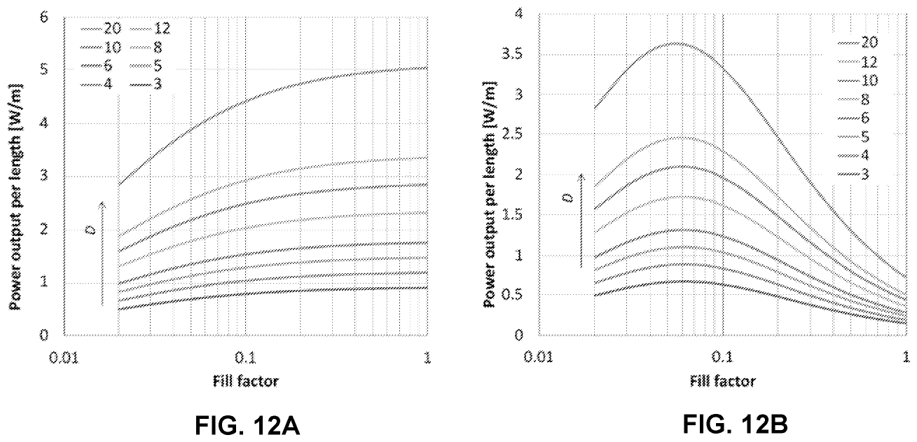

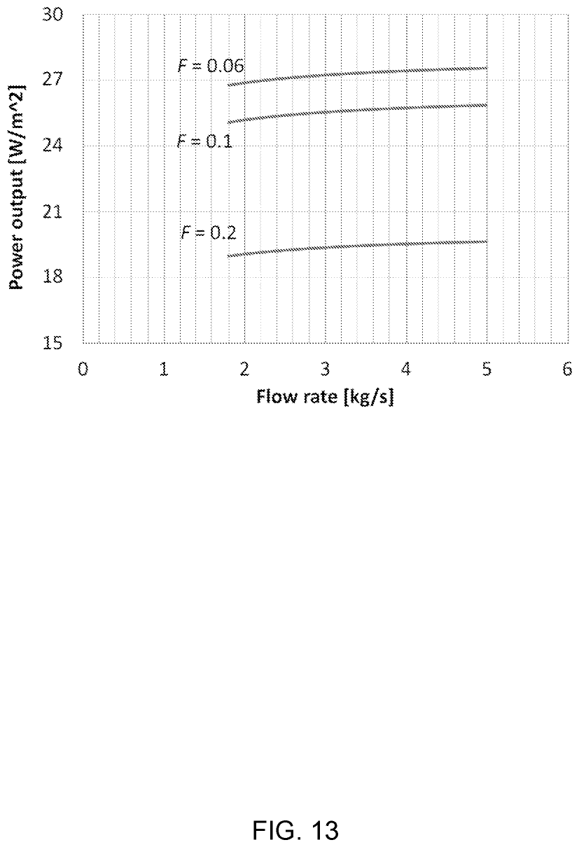

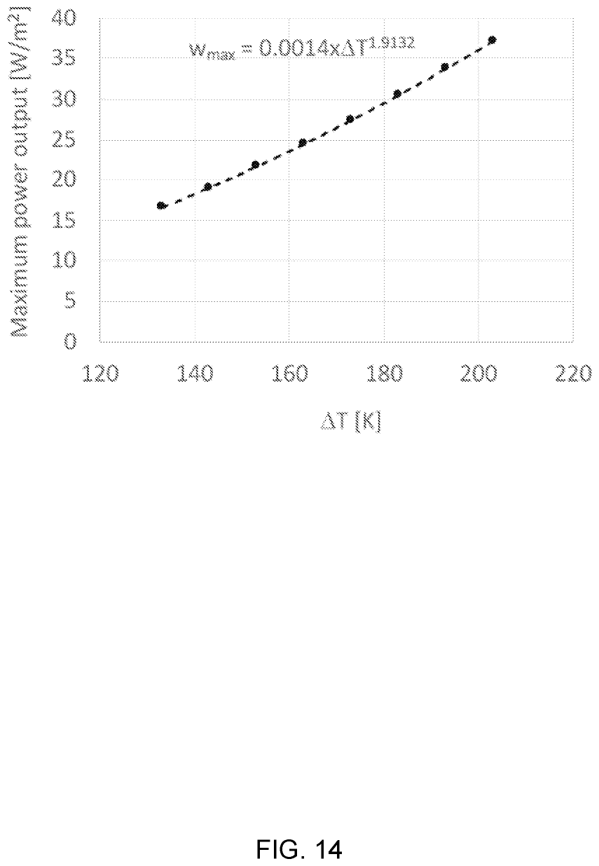

Additional investigations were performed to analyze the effects of varying pipe diameter with a fixed steam flow rate (i.e., 4 kg/s), varying steam flow rate, and varying the temperature of the steam. FIG. 12 represents the fill factor of the cTEG as a function of pipe diameter from three inches (7.6 cm) to 20 inches (50.8 cm). FIG. 12A shows the case thickness of the module is not limited. FIG. 12B shows the case leg thickness is fixed to 5 mm as previous analysis. As represented, extension of the surface area by extending the pipe diameter increased the capacity of power output for the system. FIG. 13 represents the power output as a function of flow rate for the fixed TE leg length of 5 mm. As represented, the change in power output by changing the flow rate was almost negligible. FIG. 14 represents the maximum power output as a function of temperature difference between the steam and the air surrounding the cTEG. As represented, power generation was in general near proportional to the square of the temperature difference (AT). Hence, the power output was a good indicator for health monitoring steam distribution.

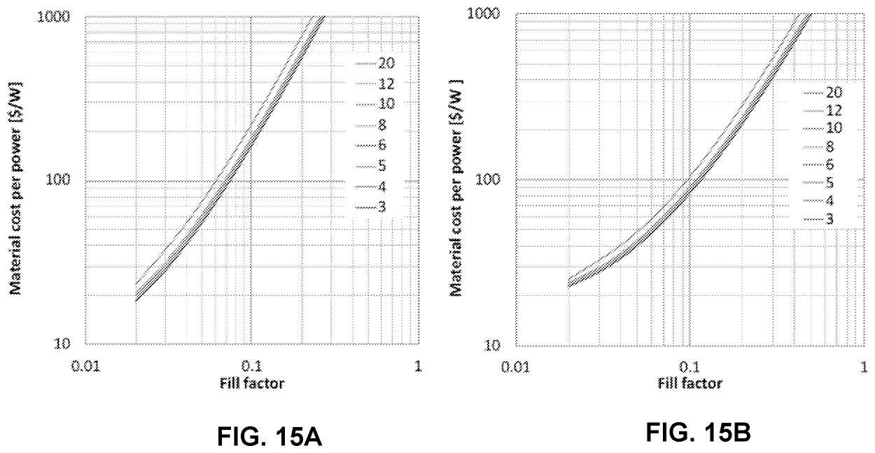

An analysis of cost impact for the cTEGs was performed. In particular, the fill factor was determined to have a significance influence on the cost to build the cTEG since the thermal impedance matching with the external contacts was a major factor to determining the maximum power output per unit area. FIG. 15A-B represents material cost per unit power output as a function of fill factor for varying pipe diameter. FIG. 15A shows the case without limiting the leg length. FIG. 15B shows the case with fixed leg length d=5 mm. As represented, the diameter of the pipe had a moderate impact to the cost. Interestingly, the cost for power was lower for the fixed length (5 mm) at a fill factor of around 3% and larger, compared to the design of optimum leg length. In comparing the cost performance in $/W with the primary batteries with bulk package in the market (see table 1), only a smaller fill factor design of cTEG was potentially a match for the initial investment and until the battery life ended. The cost including replacement and human cost thereafter only increases primary battery cost while the cTEG continues to generate power.

TABLE 1
An initial cost and energy cost of primary batteries.

| Primary | Power | Initial Cost | Capacity | Energy Cost |
|---|---|---|---|---|
| Battery Type | (W) | ($/W) | (Wh) | ($/Wh) |
| 9 V | 0.13 | 8.96 | 0.57 | 2.05 |
| AAA | 0.03 | 7.33 | 1.15 | 0.19 |
| AA | 0.03 | 8.33 | 2.87 | 0.09 |
| C | 0.06 | 28.08 | 7.8 | 0.21 |
| D | 0.06 | 36.75 | 17 | 0.12 |

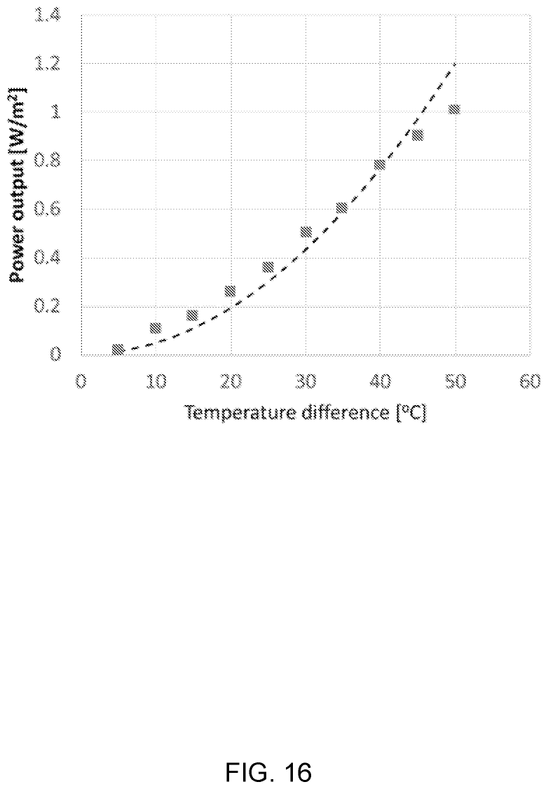

In addition to the above modeling investigations, an investigation was performed on a cTEG having eight TE legs in a 40 mm×40 mm module. FIG. 16 represents the power output per unit area as a function of the controlled temperature difference across the cTEG compared with equation (1). The dots represent experimental data, and the broken curve represents the theoretical result with the effective dimensionless figure of merit zT=4.03×10⁻² at room temperature. This zT value was significantly smaller compared to known typical values of Bi₂Te₃ because of large contact resistances with the experimental process as well as large heat losses through the PDMS gap fill. The TE leg dimensions were 0.5 mm×0.5 mm and 3.5 mm in cross section and length, respectively.

These investigations indicated the cTEG is capable of use in steam pipelines for powering IoT monitoring sensors. The optimum fill factor was observed at an aggressive number of 6.5% where the power generation was 27.4 W/m². The power output of 19.5 W/m² was found with a more reasonable fill factor of 20% and the thickness of 5 mm for mechanical conformability. It is possible that the cTEG could reach 35 W/m² or more with addition of heat fins if the thermal resistance across the cTEG could be optimized. The power and voltage output observed were determined to be more than sufficient to power a typical IoT sensor which was expected to operate within a micro-watt regime.

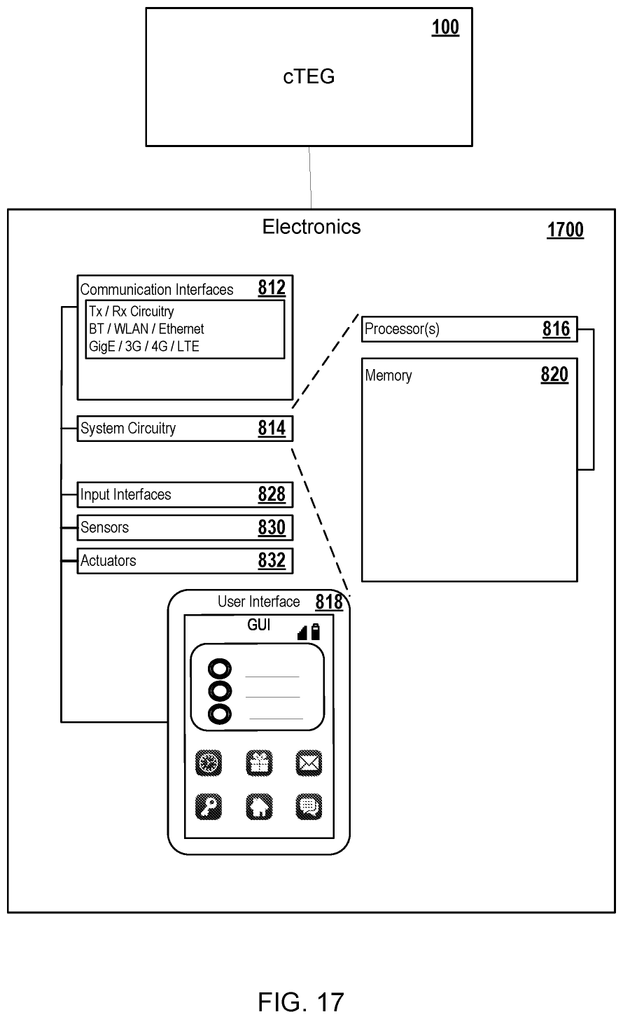

FIG. 17 illustrates an example of a system in which electronics 1700 are powered by a cTEG 102. The system may include a cTEG 100 and Electronics 1700. The electronics 1702 may include communication interfaces 812, input interfaces 828 and/or sensors and actuators system circuitry 814. The system circuitry 814 may include a processor 816 or multiple processors. Alternatively or in addition, the system circuitry 814 may include memory 820.

The processor 816 may be in communication with the memory 820. In some examples, the processor 816 may also be in communication with additional elements, such as the communication interfaces 812, the input interfaces 828, sensors 830, actuators 832, and/or the user interface 818. Examples of the processor 816 may include a general processor, a central processing unit, logical CPUs/arrays, a microcontroller, a server, an application specific integrated circuit (ASIC), a digital signal processor, a field programmable gate array (FPGA), and/or a digital circuit, analog circuit, or some combination thereof.

The processor 816 may be one or more devices operable to execute logic. The logic may include computer executable instructions or computer code stored in the memory 820 or in other memory that when executed by the processor 816, cause the processor 816 to perform the operations to control the actuators 832, user interface 818, system circuitry 814, and or communicate information obtained by, for example, sensors 830 or other IT monitoring devices.

The memory 820 may be any device for storing and retrieving data or any combination thereof. The memory 820 may include non-volatile and/or volatile memory, such as a random access memory (RAM), a read-only memory (ROM), an erasable programmable read-only memory (EPROM), or flash memory. Alternatively or in addition, the memory 820 may include an optical, magnetic (hard-drive), solid-state drive or any other form of data storage device. In some examples, the memory may include or store information or instructions that cause the CPU to perform operations as described herein.

The user interface 818 may include any interface for displaying graphical information. The system circuitry 814 and/or the communications interface(s) 812 may communicate signals or commands to the user interface 818 that cause the user interface to display graphical information. Alternatively or in addition, the user interface 818 may be remote to the electronics 1700 and the system circuitry 814 and/or communication interface(s) may communicate instructions, such as HTML, to the user interface to cause the user interface to display, compile, and/or render information content. In some examples, the content displayed by the user interface 818 may be interactive or responsive to user input. For example, the user interface 818 may communicate signals, messages, and/or information back to the communications interface 812 or system circuitry 814.

The sensors 830 may include electronics which perform data acquisition. For example, the sensors 830 may measure, for example, temperature, pressure, flow rate fluctuation, acoustic emission, localized strain, and/or any other type of measurable physical property. The actuators 832 may convert electrical signals into motion. Alternatively or in addition, the electronics 1700 may include other circuitry, such as switches, transistors, etc. which are controlled based on control signals.

The processing capability of the electronics 1700 may be distributed among multiple entities, such as among multiple processors and memories, optionally including multiple distributed processing systems. Parameters, databases, and other data structures may be separately stored and managed, may be incorporated into a single memory or database, may be logically and physically organized in many different ways, and may implemented with different types of data structures such as linked lists, hash tables, or implicit storage mechanisms. Logic, such as programs or circuitry, may be combined or split among multiple programs, distributed across several memories and processors.

In addition to steam pipeline applications, the cTEG can also be used for other heat transfer and/or heat energy harvesting applications, such as hot oil and/or spring water transfer, heating and/or cooling water pipeline networks, chilled ware supply in datacenters, etc.

While the invention has been described in terms of specific or particular embodiments and investigations, it should be apparent that alternatives could be adopted by one skilled in the art. For example, the cTEG and its components could differ in appearance and construction from the embodiments described herein and shown in the figures, functions of certain components of the cTEG could be performed by components of different construction but capable of a similar (though not necessarily equivalent) function, and various materials could be used in the fabrication of the cTEG and/or its components. Accordingly, it should be understood that the invention is not necessarily limited to any embodiment described herein. It should also be understood that the phraseology and terminology employed above are for the purpose of describing the disclosed embodiments and investigations, and do not necessarily serve as limitations to the scope of the invention. Finally, while the appended claims recite certain aspects believed to be associated with the invention as indicated by the investigations cited above, they do not necessarily serve as limitations to the scope of the invention.

What is claimed is:

1. A thin-film thermoelectric generator (TEG) comprising:
a flexible base film substrate having a longitudinal direction and a transverse direction perpendicular to the longitudinal direction;
thermoelectric (TE) elements located on the base film substrate, the TE elements arranged in columns oriented along the longitudinal direction of the base film substrate and rows oriented along the transverse direction of the base film substrate;
line grooves located between at least portion of the rows of the TE elements and extending across the base film substrate in the transverse direction;
an inter layer separating the TE elements;
bottom side contacts coupling adjacent pairs of the TE elements within the
columns across the line grooves on a bottom side of the inter layer between the base film substrate and the TE elements; and
top side contacts coupling adjacent pairs of the TE elements within the rows between the line grooves on a top side of the inter layer opposite the bottom side thereof;
wherein the TE elements are configured to convert thermal energy into electrical energy;
wherein the base film substrate and the line grooves in combination provide for the thin-film TEG to bend and conform to a curved surface.

2. The thin-film TEG of claim 1, wherein the TE elements include p-type junctions and n-type junctions.

3. The thin-film TEG of claim 1, wherein the base film substrate includes a polyimide.

4. The thin-film TEG of claim 1, wherein the base film substrate includes Kapton.

5. The thin-film TEG of claim 1, wherein the inter layer includes PDMS.

6. The thin-film TEG of claim 1, wherein the TE elements include bismuth telluride (Bi₂Te₃).

7. The thin-film TEG of claim 1, further comprising one or more fins in thermal contact with the top side of the inter layer configured to provide passive air convection cooling thereto.

8. The thin-film TEG of claim 1, further comprising one or more cutting lines along a length of the thin-film TEG that extends across the thin-film TEG in the transverse direction and that is configured to be cut to adjust the length of the thin-film TEG without affecting the operation of the thin-film TEG.

9. A method of using the thin-film TEG of claim 1 in a system for monitoring a pipeline having a fluid flowing therethrough at an elevated temperature relative to an ambient temperature surrounding the pipeline, the method comprising:
locating the thin-film TEG on a section of the pipeline such that the thin-film TEG conforms to the exterior shape of the pipeline and is exposed to heat flux radiating from the pipeline;
converting at least a portion of the heat flux radiating from the pipeline to electrical energy with the thin-film TEG; and
providing the electrical energy generated by the thin-film TEG to one or more electrical components of the system in an amount sufficient to power or recharge the one or more electrical components.

10. The method of claim 9, wherein the one or more electrical components includes at least one sensor confirmed for monitoring a parameter of the pipeline.

11. The method of claim 10, wherein the at least one sensor is connected to others of the electrical components of the system with an internet of things (IoT) technology.

12. The method of claim 9, wherein the pipeline is a steam pipeline and the fluid is steam.

13. The method of claim 9, wherein the thin-film TEG is in direct contact with the pipeline.

14. The method of claim 13, wherein the pipeline has a diameter of at least two centimeters.

15. The method of claim 9, further comprising cutting the thin-film TEG along a cutting line that extends across the thin-film TEG in the transverse direction to adjust the length of the thin-film TEG prior to locating the thin-film TEG on the section of pipeline.

16. A method of fabricating the thin-film TEG of claim 1, the method comprising:
printing the bottom side contacts on the base film substrate in a predetermined pattern;
depositing the inter layer onto the base film substrate and the top side contacts;
forming holes in the inter layer aligned with the bottom side contacts;
depositing TE materials into the holes;
sintering the TE materials to form the TE elements;
printing the top side contacts on the top side of the inter layer aligned with the TE elements; and
forming the line grooves in the inter layer.

17. The method of claim 16, wherein the TE materials are components of an ink composition.

18. The method of claim 16, further comprising depositing a top side layer on the top side of the inter layer overlaying the top side contacts prior to forming the line grooves.

19. A method of fabricating the thin-film TEG of claim 1, the method comprising:
providing a thin-film of the inter layer;
printing the bottom side contacts a bottom side of the inter layer in a predetermined pattern;
forming holes in the inter layer aligned with the bottom side contacts;
depositing TE materials into the holes;
sintering the TE materials to form the TE elements;
printing the top side contacts on the top side of the inter layer aligned with the TE elements; and
forming the line grooves in the inter layer.

20. The method of claim 19, wherein the TE materials are components of an ink composition.
